(19) United States
(12) Patent Application Publication
(10) Pub. No.: US 2012/0267695 A1
(43) Pub. Date: Oct. 25, 2012

(54) SOLID STATE IMAGING DEVICE

(76) Inventor: Hirofumi YAMASHITA, Kawasaki-shi (JP)

(21) Appl. No.: 13/428,369

(22) Filed: Mar. 23, 2012

(30) Foreign Application Priority Data
Apr. 22, 2011 (JP) 2011-096387

(51) Int. Cl. H01L 31/02

(52) U.S. Cl. 257/292; 257/E31.113

(57) ABSTRACT

According to one embodiment, a solid-state imaging device includes a pixel array unit arrayed unit pixels in a matrix pattern, each of the unit pixels including a photoelectric conversion element and a floating diffusion region, signal lines provided for respective pixel columns and configured to read signals from the unit pixels, capacitive interconnections provided for the respective pixel columns and capacitively coupled to the floating diffusion regions, first switch elements configured to switch a connection state between the signal lines and the capacitive interconnections, and second switch elements configured to switch a connection state between the capacitive interconnections and a power supply line.

### CROSS-REFERENCE TO RELATED APPLICATIONS

This application is based upon and claims the benefit of priority from prior Japanese Patent Application No. 2011-096387, filed Apr. 22, 2011, the entire contents of which are incorporated herein by reference.

### FIELD

Embodiments described herein relate generally to a solid-state imaging device.

### BACKGROUND

A solid-state imaging device is used for a variety of purposes such as a digital still camera (digital camera), a video camera, or a monitoring camera. A CCD or CMOS sensor is widely used as a solid-state imaging device.

To apply a solid-state imaging device to, for example, a digital camera, a video camera, or a monitoring camera, the following imaging properties are required. That is, the solid-state imaging device must be able to image a dark object at a high signal-to-noise ratio (S/N ratio), and have an output resolution sufficient to resolve an image captured by imaging a sufficiently bright object. When it is possible to image a dark object at a high S/N ratio and image a sufficiently bright object, that is, to capture an image with a wide dynamic range, this offers an advantage in reproducing an image with high fidelity to the object as viewed by the human eye.

However, in recent years, to keep up with a demand for downsizing a camera, a demand for downsizing an imaging optical system is becoming stronger, and a demand for a higher resolution is soaring at the same time. Hence, the pixel size continues to reduce, but this makes it difficult to capture an image with a wide dynamic range, as described above.

### BRIEF DESCRIPTION OF THE DRAWINGS

FIG. 1 is a block diagram of a solid-state imaging device 10 according to the embodiment;

FIG. 2 is a sectional view of the solid-state imaging device 10;

FIG. 3 is a timing chart showing a low-gain operation;

FIG. 4 is a timing chart showing a high-gain operation;

FIG. 5 is a graph illustrating an example of the input/output characteristics of a source follower circuit; and

FIG. 6 is a sectional view of a solid-state imaging device 10 having a front side illumination structure.

### DETAILED DESCRIPTION

In general, according to one embodiment, there is provided a solid-state imaging device comprising:

a pixel array unit arrayed unit pixels in a matrix pattern, each of the unit pixels including a photoelectric conversion element, and a floating diffusion region to which a signal charge is transferred from the photoelectric conversion element;

signal lines provided for respective pixel columns and configured to read signals from the unit pixels;

capacitive interconnections provided for the respective pixel columns and capacitively coupled to the floating diffusion regions;

first switch elements configured to switch a connection state between the signal lines and the capacitive interconnections; and

second switch elements configured to switch a connection state between the capacitive interconnections and a power supply line.

The embodiments will be described hereinafter with reference to the accompanying drawings. In the description which follows, the same or functionally equivalent elements are denoted by the same reference numerals, to thereby simplify the description.

### 1. ARRANGEMENT OF SOLID-STATE IMAGING DEVICE 10

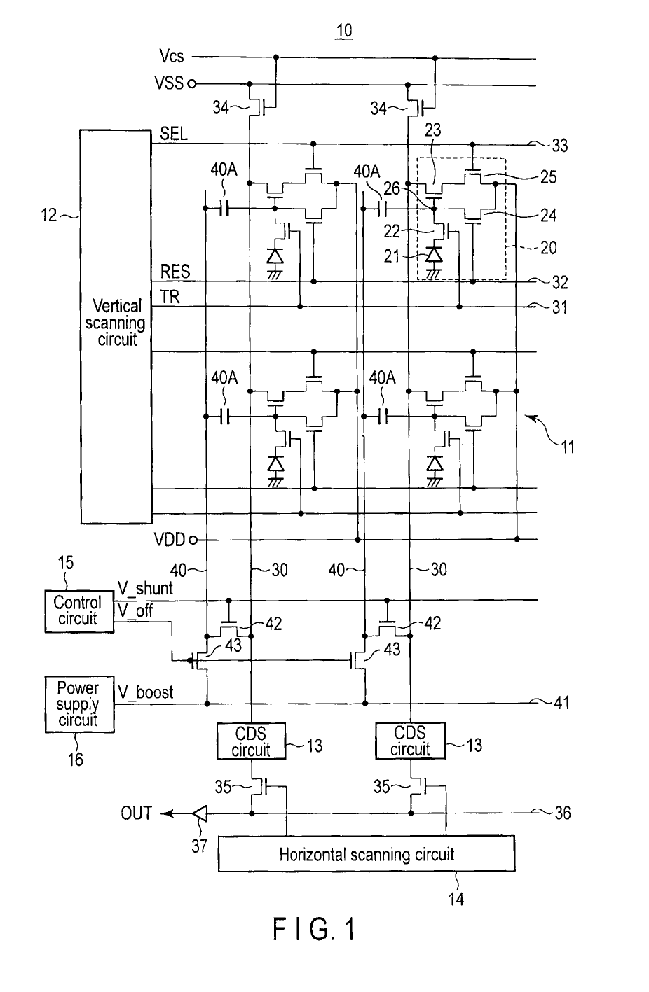

FIG. 1 is a block diagram of a solid-state imaging device 10 according to the embodiment. The solid-state imaging device 10 comprises a pixel array unit 11 formed by arraying unit pixels 20 including photoelectric conversion elements in a matrix pattern. Also, as peripheral circuits of the pixel array unit 11, the solid-state imaging device 10 comprises, for example, a vertical scanning circuit 12, correlated double-sampling (CDS) circuits 13, a horizontal scanning circuit 14, a control circuit 15, and a power supply circuit 16, as shown in FIG. 1.

In the matrix array of unit pixels (to be also simply referred to as pixels hereinafter) 20 in the pixel array unit 11, a vertical signal line 30 is arranged for each pixel column, and a transfer line 31, a reset line 32, and a select line 33 are arranged for each pixel row. A constant current source 34 is connected to one end of each vertical signal line 30. The constant current source 34 is formed by, for example, a load transistor. A load transistor serving as the constant current source 34 is formed by, for example, an n-channel MOS transistor, and has its drain connected to the vertical signal line 30, its source connected to a ground terminal having a ground voltage VSS, and its gate supplied with a load control signal Vcs from the control circuit 15. The constant current source 34 has a function of supplying a constant current to the vertical signal line 30 when signal charges are read from the unit pixels 20.

FIG. 1 shows only 2×2 pixels among the plurality of unit pixels included in the pixel array unit 11 for the sake of simplicity. Each unit pixel 20 includes a photoelectric conversion element 21, transfer transistor 22, amplifier transistor 23, reset transistor 24, select transistor 25, and floating diffusion region (detection region) 26. N-channel MOS transistors, for example, are used as these transistors 22 to 25.

A photodiode, for example, is used as the photoelectric conversion element 21. The photodiode 21 photoelectrically converts incident light into signal charges (for example, signal electrons) having an amount of charges corresponding to the amount of incident light, and stores them. The anode of the photodiode 21 is grounded. The transfer transistor 22 is connected between the floating diffusion region 26 and the cathode of the photodiode 21. The floating diffusion region 26 is formed by, for example, an n-type diffusion region formed in a semiconductor substrate. The gate of the transfer transistor 22 is connected to the transfer line 31. The transfer transistor 22 is on/off-controlled in accordance with a transfer signal TR supplied from the vertical scanning circuit 12 to the transfer line 31, and transfers the signal charges stored in the photodiode 21 to the floating diffusion region 26 when the transfer signal TR is at high level.

The reset transistor 24 has its drain connected to a power supply terminal VDD, its source connected to the floating diffusion region 26, and its gate connected to the reset line 32. The reset transistor 24 is on/off-controlled in accordance with a reset signal RES supplied from the vertical scanning circuit 12 to the reset line 32, and sets the voltage of the floating diffusion region 26 to the power supply voltage VDD when the reset signal RES is at high level.

The amplifier transistor 23 has its drain connected to the power supply terminal VDD, its source connected to the vertical signal line 30, and its gate connected to the floating diffusion region 26. The amplifier transistor 23 forms a source follower circuit, and the voltage of the vertical signal line 30 follows a fluctuation in voltage of the floating diffusion region 26. Hence, a voltage which corresponds to the amount of charges in the floating diffusion region 26 and is determined by the gate voltage of the amplifier transistor 23 appears on the vertical signal line 30. The amplifier transistor 23 outputs, as a reset level, the voltage of the floating diffusion region 26 reset by the reset transistor 24, and outputs, as a signal level, the voltage of the floating diffusion region 26 after the signal charges are transferred from the photodiode 21 via the transfer transistor 22.

The select transistor 25 has its drain connected to the power supply terminal VDD, its source connected to the drain of the amplifier transistor 23, and its gate connected to the select line 33. The select transistor 25 is on/off-controlled in accordance with a select signal SEL supplied from the vertical scanning circuit 12 to the select line 33, and activates the source follower circuit (amplifier transistor 23) when the select signal SEL is at high level.

Note that the select transistor 25 can also adopt an arrangement in which it is connected between the vertical signal line 30 and the source of the amplifier transistor 23. Also, although the unit pixel 20 employs a four-transistor structure in the embodiment, the embodiment is not limited to this, and the unit pixel 20 may employ a three-transistor structure in which the amplifier transistor 23 also serves as a select transistor.

The vertical scanning circuit 12 is connected to the transfer lines 31, reset lines 32, and select lines 33. The vertical scanning circuit 12 appropriately generates drive pulses as the transfer signal TR, reset signal RES, and select signal SEL, thereby reading pixel signals from the unit pixels 20 while sequentially scanning the pixel columns of the pixel array unit 11.

The CDS circuit 13 is formed for each pixel column of the pixel array unit 11, and performs a correlated double-sampling (CDS) process for a pixel signal output via the vertical signal line 30 from each unit pixel 20 on a read row selected by the vertical scanning circuit 12. That is, the CDS circuit 13 calculates, for example, the difference between the reset level and the signal level to perform, for example, a process of eliminating fixed pattern noise produced by each unit pixel 20. Also, the CDS circuit 13 temporarily holds the pixel signal having undergone the CDS process.

The output terminals of the CDS circuits 13 are connected to a horizontal signal line 36 via horizontal select transistors 35 formed by n-channel MOS transistors. The gates of the horizontal select transistors 35 are connected to the horizontal scanning circuit 14.

The horizontal scanning circuit 14 sequentially scans the horizontal select transistor 35 formed for each pixel column. The horizontal select transistors 35 are selected by the horizontal scanning circuit 14 to transfer the pixel signals temporarily held in the CDS circuits 13 to the horizontal signal line 36. The horizontal signal line 36 is connected to an output circuit 37. The output circuit 37 outputs the pixel signals to the outside.

Note that the pixel array unit 11 includes a capacitance adjusting interconnection 40 arranged for each pixel column. One capacitance adjusting interconnection 40 is opposed to the floating diffusion region 26 of each unit pixel 20 included in one pixel column via an insulating film, and is capacitively coupled to the floating diffusion region 26. One capacitance adjusting interconnection 40 is connected to the vertical signal line 30 on the same pixel column via a switch element (for example, an n-channel MOS transistor) 42. One end of the capacitance adjusting interconnection 40 is connected to a power supply line 41 via a switch element (for example, an n-channel MOS transistor) 43. One end of the power supply line 41 is connected to the power supply circuit 16.

The power supply circuit 16 generates various voltages required to operate the solid-state imaging device 10. Also, the power supply circuit 16 supplies a voltage V_boost to the power supply line 41.

The control circuit 15 generates timing signals and control signals serving as references for the operations of the vertical scanning circuit 12, CDS circuits 13, and horizontal scanning circuit 14, and appropriately supplies them to these circuits. Also, to control the potential of the capacitance adjusting interconnection 40, the control circuit 15 supplies a control signal V_shunt to the gate of the switch element 42, and supplies a control signal V_off to the gate of the switch element 43.

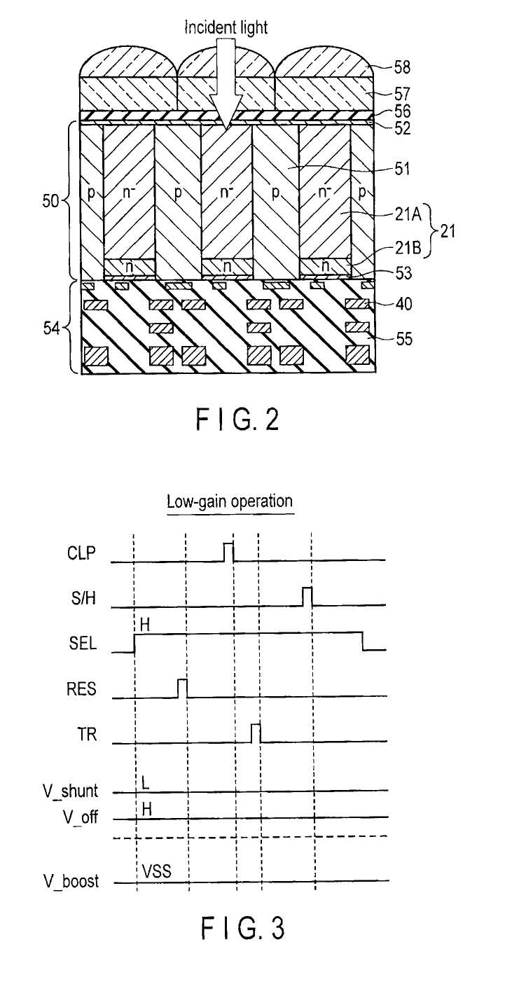

An example of the structure of the solid-state imaging device 10 will be described next. FIG. 2 is a sectional view of the solid-state imaging device 10.

A semiconductor substrate 50 is formed by, for example, a silicon (Si) substrate. A plurality of photodiodes 21 are arranged in a matrix pattern in the semiconductor substrate 50. The plurality of photodiodes 21 are electrically isolated from each other by an element isolation region 51 formed in a matrix pattern (mesh pattern). The element isolation region 51 is formed by a p-type semiconductor region.

Each photodiode 21 includes a charge storage region 21A and n-type semiconductor region 21B. The charge storage region 21A is formed by an n⁻-type semiconductor region with a low concentration, and functions as a light-receiving unit which photoelectrically converts incident light. The n-type semiconductor region 21B is formed as the lower part of the photodiode 21, and has a function of collecting charges stored in the charge storage region 21A. The two-dimensional shape of the photodiode 21 is, for example, nearly square.

A p⁺-type semiconductor region 52 is formed on the photodiodes 21. The p⁺-type semiconductor region 52 functions as an element isolation region which electrically isolates the plurality of photodiodes 21 from each other, like the element isolation region 51. p⁺-type semiconductor regions 53 are formed under the photodiodes 21. The p⁺-type semiconductor regions 53 function as a hole storage layer which depletes the electron storage regions in the photodiodes 21 to prevent any afterimage due to residual electrons.

An interconnection structure 54 including a multilayer interconnection layer is formed under the semiconductor substrate 50 (on the front side of the semiconductor substrate 50). The interconnection structure 54 includes, for example, an interlayer dielectric layer 55 formed by silicon oxide, and a multilayer metal interconnection formed in the interlayer dielectric layer 55. The interconnection structure 54 includes capacitance adjusting interconnections 40 as described earlier. The interconnection structure 54 also includes various interconnections other than the capacitance adjusting interconnection 40, and the gate electrodes of MOS transistors.

A planarizing film 56 made of silicon oxide, for example, is formed on the semiconductor substrate 50 (on the backside of the semiconductor substrate 50). A color filter 57 is formed on the planarizing film 56 for each unit pixel. The color filters 57 include red filters which mainly transmit light in the red wavelength range, green filters which mainly transmit light in the green wavelength range, and blue filters which mainly transmit light in the blue wavelength range. Microlenses (condenser lenses) 58 are formed on the color filters 57 in a number corresponding to that of pixels.

With such a structure, the solid-state imaging device 10 according to the embodiment guides light incident from the upper side in FIG. 2, and photoelectrically converts the incident light using the photodiodes 21, thereby receiving and detecting the incident light. The solid-state imaging device 10 then guides light incident from the upper side (backside) opposite to the side of the interconnection structure 54 (front side) when viewed from the semiconductor substrate 50 having the photodiodes 21 formed in it. Therefore, the solid-state imaging device 10 has a so-called backside illumination structure.

### 2. OPERATION

The operation of the solid-state imaging device 10 will be described next. A high-illuminance imaging operation in which a bright object is imaged will be described first. The high-illuminance imaging operation is an operation (to be referred to as a low-gain operation hereinafter) of increasing the capacitance of each floating diffusion region so that a large amount of signal charges can be stored in the floating diffusion region. In imaging a bright object, the amount of incident light is so large that a large number of signal charges are generated in each photodiode, thus making it necessary to store a large number of signal charges in the corresponding floating diffusion region. Hence, according to the embodiment, in the high-illuminance imaging operation, the capacitance of each floating diffusion region is increased so that a large number of signal charges can be stored in the floating diffusion region.

FIG. 3 is a timing chart showing a low-gain operation. The power supply circuit 16 sets a voltage V_boost to a ground voltage VSS. Note that the voltage V_boost is not limited to the ground voltage VSS, and may be a power supply voltage VDD or an intermediate voltage between the ground voltage VSS and the power supply voltage VDD.

The control circuit 15 sets a control signal V_off to a high-level voltage (for example, the power supply voltage VDD). This turns on the switch element 43 to electrically connect the power supply line 41 to the capacitance adjusting interconnection 40. The control circuit 15 also sets a control signal V_shunt to a low-level voltage (for example, the ground voltage VSS). This turns off the switch element 42 to electrically isolate the capacitance adjusting interconnection 40 and the vertical signal line 30 from each other. As a result, a predetermined capacitance 40A is added to the floating diffusion region 26 of each unit pixel 20 by the capacitance adjusting interconnection 40.

The vertical scanning circuit 12 sets a select signal SEL corresponding to a pixel row from which a pixel signal is to be read (to be referred to as a selected row hereinafter) to a high-level voltage to turn on the select transistor 25 included in the selected row.

The floating diffusion region 26 is reset. That is, the vertical scanning circuit 12 outputs a pulsed reset signal RES to the selected row. This turns on the reset transistor 24 to reset the floating diffusion region 26 to the power supply voltage VDD. The potential of the floating diffusion region 26 is output to the vertical signal line 30 as a reset level.

The control circuit 15 supplies a pulsed clamp signal CLP to the CDS circuit 13. Upon this operation, the CDS circuit 13 clamps, via the vertical signal line 30, the potential (reset level) of the floating diffusion region 26 at the time of reset.

The vertical scanning circuit 12 outputs a pulsed transfer signal TR to the selected row. This turns on the transfer transistor 22 to transfer the signal charges stored in the photodiode 21 to the floating diffusion region 26. The potential of the floating diffusion region 26 is output to the vertical signal line 30 as a signal level.

The control circuit 15 supplies a pulsed sample/hold signal S/H to the CDS circuit 13. Upon this operation, the CDS circuit 13 clamps, via the vertical signal line 30, the potential (signal level) of the floating diffusion region 26 to which the signal charges are transferred. The CDS circuit 13 calculates the difference between the reset level and the signal level and holds the obtained difference voltage (pixel signal).

The horizontal select transistors 35 on the respective pixel columns are driven in accordance with horizontal select pulses sequentially output from the horizontal scanning circuit 14, thereby outputting pixel signals having undergone a CDS process by the CDS circuits 13 from the output circuit 37 via the horizontal signal line 36.

In this manner, in the low-gain operation, the capacitance 40A between the newly formed capacitance adjusting interconnection 40 and the floating diffusion region 26 is added to that of the floating diffusion region 26, so a larger number of signal charges can be stored in the floating diffusion region 26 than without the capacitance adjusting interconnection 40. Therefore, even when an object illuminated with a large amount of light is imaged, a sufficiently large number of signal charges can be stored in the floating diffusion region 26, thus obtaining an image with a wide dynamic range.

A low-illuminance imaging operation in which a dark object is imaged will be described next. The low-illuminance imaging operation is an operation (to be referred to as a high-gain operation hereinafter) of decreasing the capacitance of each floating diffusion region so as to increase the gain of the corresponding pixel. As the pixel size reduces, the amount of light that can be received by each photodiode also reduces, so the sensitivity degrades. In this case, to maintain a given signal-to-noise ratio (S/N ratio), it is necessary to keep noise produced by each pixel as low as possible. Hence, according to the embodiment, in the low-illuminance imaging operation, the capacitance of each floating diffusion region is decreased so as to increase the output voltage from the floating diffusion region per signal charge.

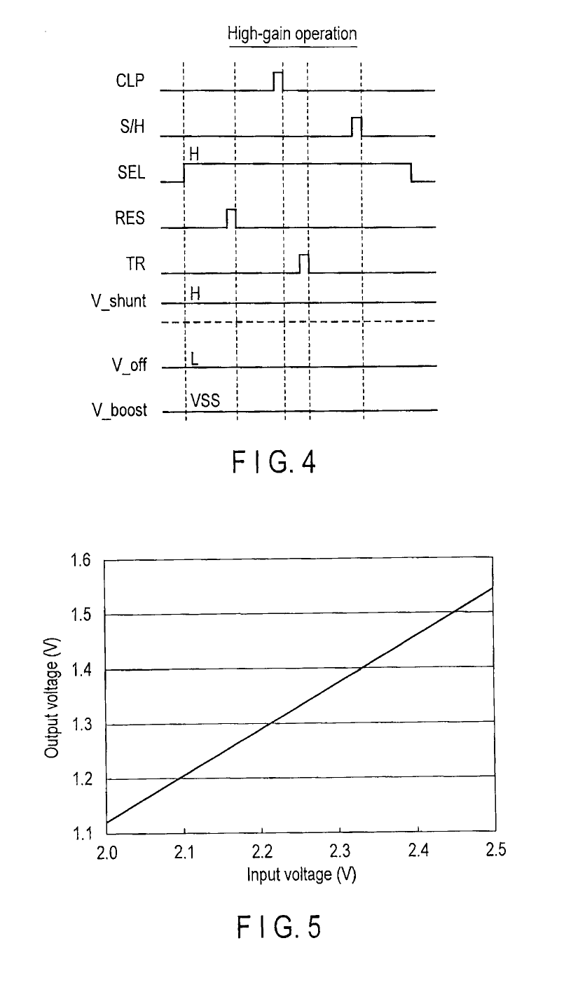

FIG. 4 is a timing chart showing a high-gain operation. The power supply circuit 16 sets a voltage V_boost to a ground voltage VSS. Note that the voltage V_boost is not limited to the ground voltage VSS, and may be a power supply voltage VDD or an intermediate voltage between the ground voltage VSS and the power supply voltage VDD, as in the low-gain operation.

The control circuit 15 sets a control signal V_off to a low-level voltage. This turns off the switch element 43 to electrically isolate the capacitance adjusting interconnection 40 and the power supply line 41 from each other. The control circuit 15 also sets a control signal V_shunt to a high-level voltage. This turns on the switch element 42 to electrically connect the capacitance adjusting interconnection 40 and the vertical signal line 30 to each other. In this state, a pixel signal is read from the unit pixel 20. The pixel signal read operation in the high-gain operation is the same as in the low-gain operation.

In this manner, when the capacitance adjusting interconnection 40 and the vertical signal line 30 are short-circuited in the high-gain operation, the following advantage can be provided. Since the amplifier transistor 23 forms a source follower circuit, a change in potential of the floating diffusion region 26 almost directly appears as that of the vertical signal line 30. Accordingly, the effective capacitance between the floating diffusion region 26 and the capacitance adjusting interconnection 40 connected to the vertical signal line 30 is lower than the physical capacitance between them.

FIG. 5 is a graph illustrating an example of the input/output characteristics of the source follower circuit. The input voltage means the voltage applied to the gate of the amplifier transistor 23 which forms the source follower circuit, that is, the potential of the floating diffusion region 26. The output voltage means the voltage applied to the source of the amplifier transistor 23, that is, the potential of the vertical signal line 30. As shown in FIG. 5, the input and output voltages from the source follower circuit satisfy the relationship:

Output Voltage=m×(Input Voltage)+V0

where V0 is a constant, and m is a coefficient representing the ratio of the change in output voltage to that in input voltage. The coefficient m is, for example, about 0.85. That is, when the input voltage changes by 1 V, the output voltage changes by 0.85 V. In such a case, an effective capacitance Ceff is given by:

Ceff=C×(1−m)

where C is the capacitance between the floating diffusion region 26 and vertical signal line 30 on the selected row.

This is because when a source follower operation is in progress, the potential difference between the floating diffusion region 26 and the vertical signal line 30 reduces to its value multiplied by a factor of (1−m), and then the change in amount of charges stored in the capacitance between the floating diffusion region 26 and the vertical signal line 30 reduces to its value multiplied by a factor of (1−m), so the capacitance apparently decreases. In an example shown in FIG. 5, the effective capacitance Ceff between the floating diffusion region 26 and the vertical signal line 30 decreases to about 0.15 of the physical capacitance. Hence, short-circuiting the capacitance adjusting interconnection 40 and the vertical signal line 30 makes it possible to decrease the effective capacitance between the capacitance adjusting interconnection 40 and the floating diffusion region 26, for the same reason as mentioned above. That is, in the high-gain operation according to the embodiment, even when the capacitance is physically added to the floating diffusion region 26 by the capacitance adjusting interconnection 40, this exerts an influence as little as about 15% of the physical capacitance.

In such a high-gain operation, the capacitance of the floating diffusion region 26 can be lower than in the above-mentioned low-gain operation. This makes it possible to keep the signal voltage high relative to the level of noise produced by each pixel and its subsequent circuits, thus improving the S/N ratio in low-illuminance imaging which uses a small number of signal electrons.

### 3. EFFECT

As described in detail above, according to the embodiment, the capacitance adjusting interconnection 40 is newly formed for each pixel column of the pixel array unit 11. The capacitance adjusting interconnection 40 is capacitively coupled to the floating diffusion region 26 of each unit pixel 20. In a first imaging mode (a high-illuminance imaging operation, that is, a low-gain operation), a predetermined voltage is applied to the capacitance adjusting interconnection 40 to add a given capacitance to the floating diffusion region 26. However, in a second imaging mode (a low-illuminance imaging operation, that is, a high-gain operation), the capacitance adjusting interconnection 40 and the vertical signal line 30 are electrically connected to each other using the switch element 42 to make the capacitance of the floating diffusion region 26 lower than that in high-illuminance imaging.

Therefore, according to the embodiment, in high-illuminance imaging, the capacitance of the floating diffusion region 26 can be increased, so a larger number of signal charges can be stored in the floating diffusion region 26. This makes it possible to widen the dynamic range of the solid-state imaging device 10. However, in low-illuminance imaging, the capacitance of the floating diffusion region 26 can be decreased, so the output voltage from the floating diffusion region per signal charge increases. This makes it possible to increase the gain so as to obtain an image with a high S/N ratio.

That is, it is possible to attain a solid-state imaging device 10 capable of obtaining a high S/N ratio in imaging a dark object, and capturing an image with a wide dynamic range in imaging a sufficiently bright object. Also, as the S/N ratio improves, degradation in light reception sensitivity can be suppressed even when the amount of light received by each photodiode reduces with a reduction in pixel size.

Also, in the embodiment, each unit pixel 20 requires no additional element as a configuration for obtaining the above-mentioned effect. Hence, the above-mentioned effect can be obtained without increasing the pixel size. This makes it possible to miniaturize each unit pixel 20.

Moreover, when the solid-state imaging device 10 employs a backside illumination structure, incident light is guided from the backside of the semiconductor substrate 50 opposite to the interconnection layer side instead of being guided from the side of the interconnection structure 54 (front side) with respect to the semiconductor substrate 50, the characteristics such as the sensitivity do not degrade even when the capacitance adjusting interconnection 40 is newly added to the interconnection structure 54.

### 4. EXAMPLE

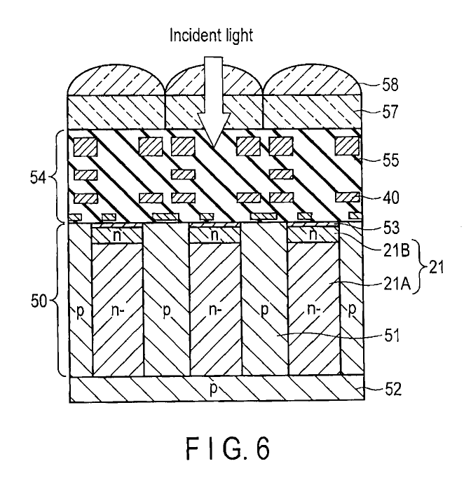

Note that the solid-state imaging device 10 according to the embodiment is not limited to a backside illumination structure, and may employ a front side illumination structure. FIG. 6 is a sectional view of a solid-state imaging device 10 having a front side illumination structure.

A p⁺-type semiconductor region 52 is formed in a semiconductor substrate 50. A plurality of photodiodes 21 are formed on the p⁺-type semiconductor region 52. P⁺-type semiconductor regions 53 are formed on the photodiodes 21. The plurality of photodiodes 21 are electrically isolated from each other by an element isolation region 51 formed in a grid pattern.

An interconnection structure 54 including a multilayer interconnection layer is formed on the semiconductor substrate 50. The interconnection structure 54 includes a capacitance adjusting interconnection 40 as described earlier. The interconnection structure 54 also includes various interconnections other than the capacitance adjusting interconnection 40, and the gate electrodes of MOS transistors. Color filters 57 and microlenses 58 are formed on the interconnection structure 54.

The solid-state imaging device 10 according to the Example guides light incident from the front side on which the interconnection structure 54 present on the lower side when viewed from the semiconductor substrate 50 having the photodiodes 21 formed on it is formed, and therefore has a so-called front side illumination structure.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device comprising:
a pixel array unit arrayed unit pixels in a matrix pattern, each of the unit pixels including a photoelectric conversion element, and a floating diffusion region to which a signal charge is transferred from the photoelectric conversion element;
signal lines provided for respective pixel columns and configured to read signals from the unit pixels;
capacitive interconnections provided for the respective pixel columns and capacitively coupled to the floating diffusion regions;
first switch elements configured to switch a connection state between the signal lines and the capacitive interconnections; and
second switch elements configured to switch a connection state between the capacitive interconnections and a power supply line.

2. The device of claim 1, wherein the capacitive interconnections are capacitively coupled to the floating diffusion regions in a first imaging mode, and are electrically connected to the signal lines in a second imaging mode.

3. The device of claim 2, wherein a gain of the unit pixel increases in the first imaging mode, and decreases in the second imaging mode.

4. The device of claim 1, further comprising a control circuit configured to turn off the first switch elements and turn on the second switch elements in the first imaging mode, and to turn on the first switch elements and turn off the second switch elements in the second imaging mode.

5. The device of claim 1, further comprising a power supply circuit configured to apply a predetermined voltage to the power supply line.

6. The device of claim 5, wherein the predetermined voltage is one of a ground voltage, a power supply voltage, and an intermediate voltage between the ground voltage and the power supply voltage.

7. The device of claim 1, wherein
each of the first switch elements has one end connected to a corresponding one of the signal lines, and the other end connected to a corresponding one of the capacitive interconnections, and
each of the second switch elements has one end connected to a corresponding one of the capacitive interconnections, and the other end commonly connected to the power supply line.

8. The device of claim 1, further comprising a current source connected to the signal lines,
wherein the unit pixel includes an amplifier transistor having a gate connected to the floating diffusion region, and a source connected to a corresponding one of the signal lines.

9. The device of claim 1, further comprising:
a semiconductor layer in which the photoelectric conversion element is provided; and
an interconnection structure provided on a first surface of the semiconductor layer,
wherein the semiconductor layer receives light incident from a second surface opposite to the first surface.

10. The device of claim 9, wherein the capacitive interconnections are included in the interconnection structure.

11. The device of claim 1, further comprising:
a semiconductor layer in which the photoelectric conversion element is provided; and
an interconnection structure provided on a first surface of the semiconductor layer,
wherein the semiconductor layer receives light incident from the first surface.

12. The device of claim 11, wherein the capacitive interconnections are included in the interconnection structure.
